(19) United States
(12) Patent Application Publication
(10) Pub. No.: US 2019/0304972 A1
(43) Pub. Date: Oct. 3, 2019

(54) SEMICONDUCTOR DEVICE

(71) Applicant: Samsung Electronics Co., Ltd., Suwon-si (KR)

(72) Inventors: Juyoun KIM, Suwon-si (KR); Jin-Wook KIM, Hwaseong-si (KR)

(21) Appl. No.: 16/260,275

(22) Filed: Jan. 29, 2019

(30) Foreign Application Priority Data
Apr. 2, 2018 (KR) 10-2018-0037937

(51) Int. Cl. H01L 27/088; H01L 29/66; H01L 29/78; H01L 29/49; H01L 21/28; H01L 21/8234

(52) U.S. Cl. CPC H01L 27/0886; H01L 29/66545; H01L 29/7851; H01L 21/823437; H01L 21/28088; H01L 21/823431; H01L 29/4966

(57) ABSTRACT

A semiconductor device includes a substrate, an interlayer dielectric layer on the substrate and having a first opening and a second opening, a first gate pattern in the first opening and including a first work function pattern, a first conductive blocking pattern, a first blocking pattern, and a conductive pattern that are stacked, and a second gate pattern in the second opening. The second gate pattern includes a second work function pattern of a material the same as a material of the first work function pattern, and a second conductive blocking pattern on the second work function pattern and filling the second opening. The second conductive blocking pattern includes a material that is different from a material of the conductive pattern and is different from a material of the first blocking pattern.

### CROSS-REFERENCE TO RELATED APPLICATION

This U.S. nonprovisional application claims priority under 35 U.S.C. § 119 to Korean Patent Application No. 10-2018-0037937 filed on Apr. 2, 2018 in the Korean Intellectual Property Office, the entire contents of which are incorporated by reference herein.

### FIELD

The inventive concepts relate to semiconductor devices, and more particularly, to semiconductor devices including transistors and methods of fabricating the same.

### BACKGROUND

Semiconductor devices may be beneficial in electronic industry because of their small size, multi-functionality, and/or low fabrication cost. Semiconductor devices may encompass semiconductor memory devices that store logic data, semiconductor logic devices that process operations of logic data, and hybrid semiconductor devices having both memory and logic elements. Semiconductor devices have been increasingly required for high integration with the advanced development of electronic industry. For example, semiconductor devices have been increasingly requested for high reliability, high speed, and/or multi-functionality.

### SUMMARY

Some example embodiments of inventive concepts provide a semiconductor device having improved threshold voltage characteristics.

Some example embodiments of inventive concepts provide a semiconductor device having improved reliability.

Embodiments of inventive concepts are not limited to those the mentioned above, and other embodiments which have not been explicitly mentioned above will be clearly understood to those skilled in the art from the following description.

According to example embodiments of inventive concepts, a semiconductor device may comprise: a substrate; an interlayer dielectric layer on the substrate and having a first opening and a second opening; a first gate pattern in the first opening and comprising a first work function pattern, a first conductive blocking pattern, a first blocking pattern, and a conductive pattern that are stacked, the conductive pattern filling the first opening; and a second gate pattern in the second opening. The second gate pattern may comprise: a second work function pattern comprising a material the same as a material of the first work function pattern; and a second conductive blocking pattern on the second work function pattern and filling the second opening. The second conductive blocking pattern may comprise a material different from a material of the conductive pattern and different from a material of the first blocking pattern.

According to example embodiments of inventive concepts, a semiconductor device may comprise: a substrate having an active pattern; and a first gate pattern extending across the active pattern. The first gate pattern may comprise: a first work function pattern on the substrate; a first conductive blocking pattern on the first work function pattern; a first blocking pattern on the first conductive blocking pattern and having an amorphous structure; and a conductive pattern on the first blocking pattern.

According to example embodiments of inventive concepts, a semiconductor device may comprise: a substrate; an interlayer dielectric layer on the substrate and having a first opening and a second opening; a first gate pattern in the first opening; and a second gate pattern in the second opening. The first gate pattern may comprise: a first upper work function pattern on a floor surface and a sidewall of the first opening; a first conductive blocking pattern on the first upper work function pattern; a first blocking pattern on the first conductive blocking pattern; and a conductive pattern on the first blocking pattern and filling the first opening. The second gate pattern may comprise: a second upper work function pattern comprising a material the same as a material of the first upper work function pattern; and a second conductive blocking pattern on the second upper work function pattern and filling the second opening. The second conductive blocking pattern may comprise a material the same as a material of the first conductive blocking pattern.

### BRIEF DESCRIPTION OF THE DRAWINGS

FIG. 1 illustrates a plan view showing a semiconductor device according to example embodiments of inventive concepts.

FIG. 2A illustrates a cross-sectional view taken along lines I-I′ and II-IF of FIG. 1.

FIG. 2B illustrates a cross-sectional view taken along lines and IV-IV′ of FIG. 1.

FIG. 2C illustrates an enlarged view showing section V of FIG. 2A.

FIGS. 3A, 4A, 5A, 6A, and 7A illustrate cross-sectional views taken along lines I-I′ and II-IF of FIG. 1, showing methods of fabricating a semiconductor device according to example embodiments of inventive concepts.

FIGS. 3B, 4B, 5B, 6B, and 7B illustrate cross-sectional views taken along lines and IV-IV′ of FIG. 1, showing methods of fabricating a semiconductor device according to example embodiments of inventive concepts.

### DETAILED DESCRIPTION OF EMBODIMENTS

In this description, like reference numerals may indicate like components. The following describes semiconductor devices and methods of fabricating the same according to inventive concepts.

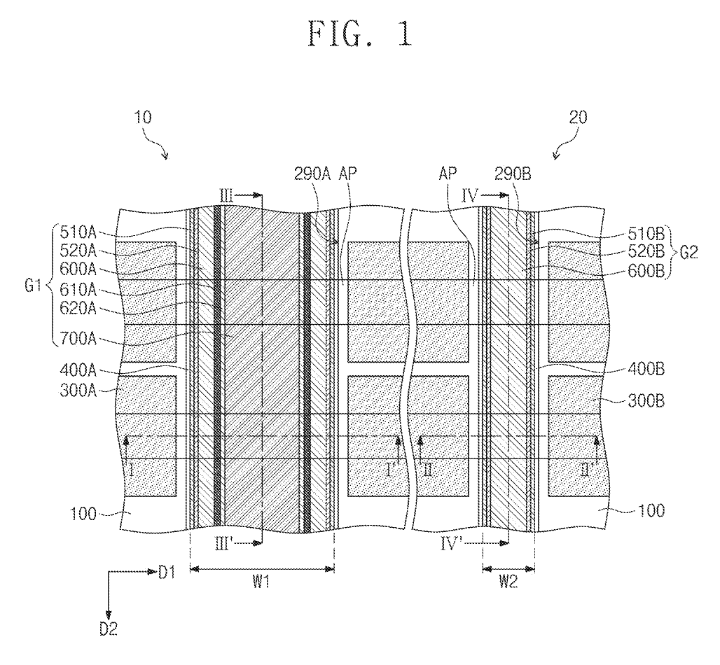

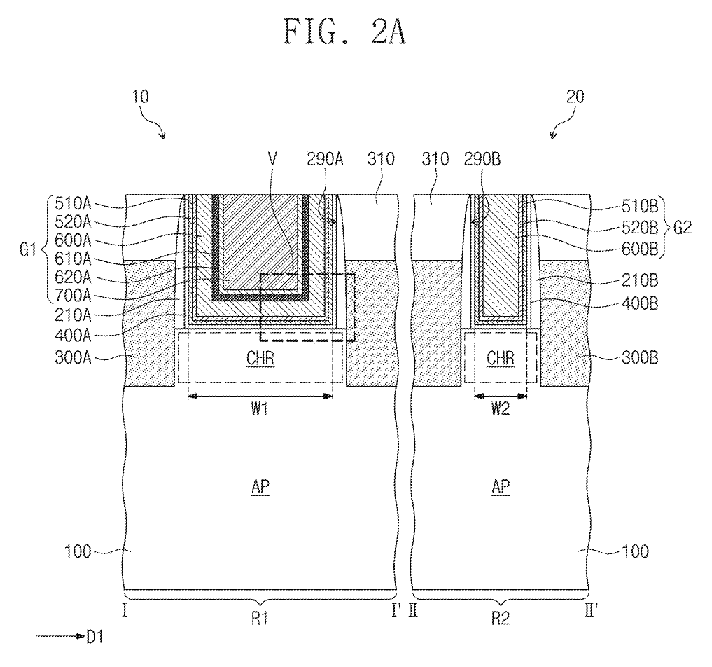

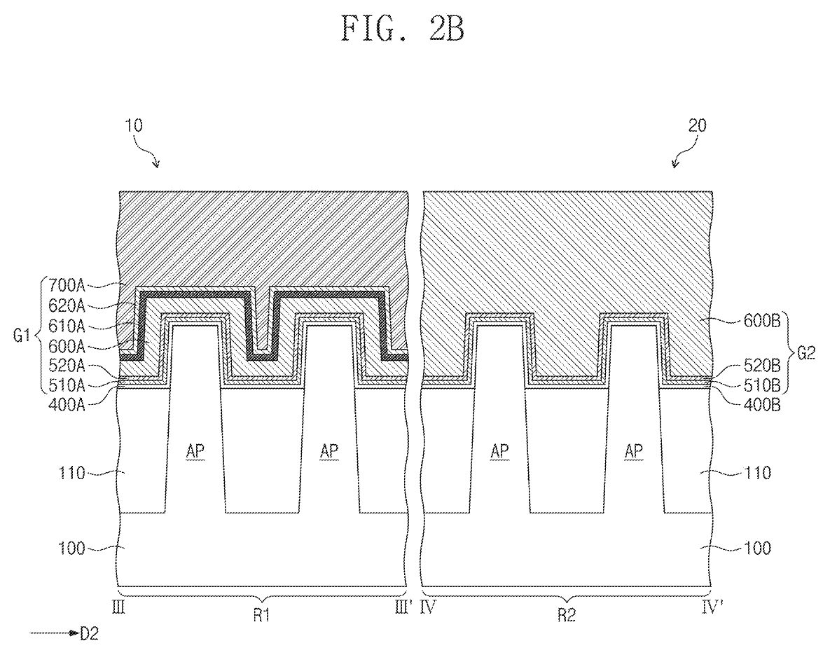

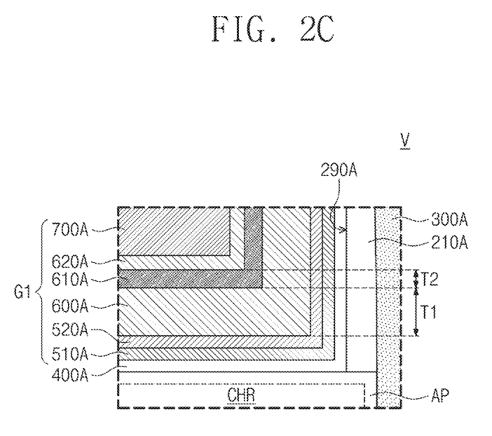

FIG. 1 illustrates a plan view showing a semiconductor device according to example embodiments of inventive concepts. FIG. 2A illustrates a cross-sectional view taken along lines I-I′ and II-IF of FIG. 1. FIG. 2B illustrates a cross-sectional view taken along lines and IV-IV′ of FIG. 1.

Referring to FIGS. 1, 2A, and 2B, a semiconductor device may include a substrate 100, an interlayer dielectric layer 310, a first transistor 10, and a second transistor 20. The terms first, second, third, etc. are used herein merely to distinguish or differentiate one element (e.g., layer, transistor, etc.) from another. The substrate 100 may have a first region R1 and a second region R2. The substrate 100 may be, for example, a silicon substrate, a germanium substrate, a silicon-germanium substrate, or an epitaxial substrate. For another example, the substrate 100 may include indium antimony, lead tellurium, indium arsenic, indium phosphorous, gallium arsenic, or gallium antimony.

An active pattern AP may protrude from the substrate 100. The active pattern AP may extend in parallel to a first direction D1. The first direction D1 may be parallel to a bottom surface of the substrate 100. The active pattern AP may be formed of a semiconductor material. For example, the active pattern AP may be formed of silicon. The active pattern AP may correspond to a portion of the substrate 100. For example, the active pattern AP and the substrate 100 may be connected to each other without a boundary therebetween. For another example, the active pattern AP may include an epitaxial layer grown from the substrate 100. The active pattern AP may further include a dopant.

A device isolation pattern 110 may be provided on the substrate 100 and may extend on or cover lower sidewalls of the active pattern AP. The device isolation pattern 110 may expose an upper portion of the active pattern AP. An active fin may be defined to indicate the upper portion of the active pattern AP, which upper portion is exposed by the device isolation pattern 110. The device isolation pattern 110 may include an insulating material. For example, the device isolation pattern 110 may include silicon oxide, silicon nitride, or silicon oxynitride.

The interlayer dielectric layer 310 may be provided on the substrate 100. The interlayer dielectric layer 310 may include an insulating material, such as silicon oxide, silicon nitride, silicon carbide, or silicon oxynitride. A first opening 290A and a second opening 290B may be provided in the interlayer dielectric layer 310. The first opening 290A may be provided on the first region R1 of the substrate 100. The second opening 290B may be provided on the second region R2 of the substrate 100. Each of the first and second openings 290A and 290B may expose a channel region CHR of the active pattern AP. The first opening 290A may have a width greater than a width of the second opening 290B.

The first transistor 10 may be provided on the first region R1 of the substrate 100. The first transistor 10 may include first source/drain patterns 300A, a first gate dielectric pattern 400A, and a first gate pattern G1. The following describes in detail the first transistor 10 in conjunction together with FIG. 2C.

Referring to FIGS. 1, 2A, 2B, and 2C, the first gate dielectric pattern 400A may be interposed between the first gate pattern G1 and the channel region CHR of the active pattern AP and between the first gate pattern G1 and the interlayer dielectric layer 310. The first gate dielectric pattern 400A may have a U-shaped cross-section. For example, the first gate dielectric pattern 400A may extend on or cover a floor surface and a sidewall of the first opening 290A. The first gate dielectric pattern 400A may include silicon oxide, silicon nitride, silicon oxynitride, or a high-k dielectric material. The high-k dielectric material may have a dielectric constant greater than that of silicon oxide. For example, the high-k dielectric material may include a hafnium-based material (e.g., HfO₂, HfSiO, HfSiON, HfON, HfAlO, or HfLaO), a silicate-based material (e.g., AlSiO or TaSiO), a zirconium-based material (e.g., ZrO₂ or ZrSiO), a lanthanide-based material (e.g., La₂O₃, Pr₂O₃, or Dy₂O₃), and/or quaternary oxide (e.g., BST ((Ba, Sr)TiO₃) or PZT (Pb(Zr, Ti)O₃)).

The first gate pattern G1 may be provided in the first opening 290A of the interlayer dielectric layer 310 and may extend on or cover the first gate dielectric pattern 400A. The first gate pattern G1 may extend in parallel to a second direction D2 and may extend across the active pattern AP. The second direction D2 may be parallel to the bottom surface of the substrate 100 and may intersect the first direction D1. The active pattern AP below the first gate pattern G1 may serve as the channel region CHR. The first gate pattern G1 may have a width W1 ranging from 30 nm to 200 nm.

The first gate pattern G1 may include first work function patterns 510A and 520A, a first conductive blocking pattern 600A, a first blocking pattern 610A, a second blocking pattern 620A, and a conductive pattern 700A. The first work function patterns 510A and 520A may include a first lower work function pattern 510A and a first upper work function pattern 520A. The first lower work function pattern 510A may extend on or cover the first gate dielectric pattern 400A. The first upper work function pattern 520A may be provided on the first lower work function pattern 510A. Each of the first work function patterns 510A and 520A may be provided on the floor surface and the sidewall of the first opening 290A. Each of the first work function patterns 510A and 520A may be formed of a conductive material having a predetermined work function, and may contribute to controlling a threshold voltage of the first transistor 10. The first lower work function pattern 510A may include, for example, a p-type work function material. The first lower work function pattern 510A may be nitride or carbide including one or more of Ti, Ta, Hf, Mo, or Al. For example, the first lower work function pattern 510A may include titanium nitride (TiN). The first upper work function pattern 520A may have a work function different from that of the first lower work function pattern 510A. The first upper work function pattern 520A may include, for example, an n-type work function material. The first upper work function pattern 520A may include aluminum (Al) and metal carbide. The metal carbide may be a compound where carbon (C) is combined with one or more of Ti, Ta, W, Ru, Nb, Mo, Hf, or La. For example, the first upper work function pattern 520A may include titanium aluminum carbide (TiAlC). Differently from that shown, one or more of the first lower work function pattern 510A or the first upper work function pattern 520A may not be provided.

The first conductive blocking pattern 600A, the first blocking pattern 610A, and the second blocking pattern 620A may be stacked on the first upper work function pattern 520A. Each of the first conductive blocking pattern 600A, the first blocking pattern 610A, and the second blocking pattern 620A may have a U-shaped cross-section. For example, each of the first conductive blocking pattern 600A, the first blocking pattern 610A, and the second blocking pattern 620A may be provided on the floor surface and the sidewall of the first opening 290A.

The first conductive blocking pattern 600A may have a crystalline structure. The first conductive blocking pattern 600A may include metal nitride, such as TiN, TaN, WN, HfN, TiAlN, TaAlN, or HfAlN.

The first blocking pattern 610A may have an amorphous structure. The first blocking pattern 610A may include a material different from that of the first conductive blocking pattern 600A. For example, the first blocking pattern 610A may include nitride, such as TaN, WN, HfN, TiAlN, TaAlN, HfAlN, or SiN. For another example, the first blocking pattern 610A may include oxide, such as hafnium oxide (e.g., HfOx) or silicon oxide (e.g., SiOx).

The second blocking pattern 620A may have a crystalline structure. The second blocking pattern 620A may include a material the same as that of the first conductive blocking pattern 600A, but inventive concepts are not limited thereto. For example, the second blocking pattern 620A may include metal nitride, such as TiN, TaN, WN, HfN, TiAlN, TaAlN, or HfAlN.

The conductive pattern 700A may be provided on the second blocking pattern 620A and may fill the first opening 290A. An element or layer that “fills” an opening or region may completely or partially fill the opening or region. The conductive pattern 700A may include tungsten (W), aluminum (Al), or an alloy of tungsten. The conductive pattern 700A may be in direct contact with the second blocking pattern 620A. When an element or layer is referred to herein as being “on” or “adjacent” or “coupled to” or “in contact with” another element or layer, intervening elements or layers may be present. In contrast, the terms “directly on” or “directly adjacent” or “directly coupled” or “in direct contact with” may mean that there are no intervening elements or layers present. The second blocking pattern 620A may have an excellent adhesion force to the conductive pattern 700A.

FIG. 2C illustrates an enlarged view showing section V of FIG. 2A. The following further describes in detail the first conductive blocking pattern 600A, the first blocking pattern 610A, and the second blocking pattern 620A.

The formation of the first gate pattern G1 may produce impurities such as oxygen. When impurities are introduced into the first gate dielectric pattern 400A, a threshold voltage of the first transistor 10 may deviate from a desired range. In some embodiments, since the first conductive blocking pattern 600A, the first blocking pattern 610A, and the second blocking pattern 620A are provided, when the first gate pattern G1 is formed, impurities may be reduced or prevented from being introduced into the first gate dielectric pattern 400A. Accordingly, the threshold voltage of the first transistor 10 may be stably controlled.

A moving path of impurities in a component may be dependent on crystallinity of the component. For example, impurities may be more difficult to pass through an amorphous component than a crystalline component. When impurities are intended to pass through the amorphous component, it may be required that impurities should travel an extremely long path. In some embodiments, the first blocking pattern 610A may have an amorphous structure. Therefore, even if impurities were to pass through the second blocking pattern 620A, the impurities may have difficulty in passing through the first blocking pattern 610A. For example, the first blocking pattern 610A may trap the impurities therein. In some embodiments, the first gate pattern G1 may include the first blocking pattern 610A such that the impurities may have greater difficulty in reaching the first gate dielectric pattern 400A.

When the first blocking pattern 610A has an excessively increased thickness T2, the first gate pattern G1 may increase in resistance. For example, when the thickness T2 of the first blocking pattern 610A is greater than 50 Å, the first gate pattern G1 may have a markedly increased resistance. In some embodiments, the thickness T2 of the first blocking pattern 610A may be less than a thickness T1 of the first conductive blocking pattern 600A. For example, the first blocking pattern 610A may have a thickness ranging from more than 0 Å to equal to or less than 50 Å. The first gate pattern G1 may thus have a relatively small resistance.

An adhesion force between the second blocking pattern 620A and the conductive pattern 700A may be greater than an adhesion force between the first blocking pattern 610A and the conductive pattern 700A. The first blocking pattern 610A and the conductive pattern 700A may be in contact with each other with the second blocking pattern 620A interposed therebetween. The second blocking pattern 620A may allow the conductive pattern 700A to satisfactorily adhere to the first blocking pattern 610A.

Referring back to FIGS. 1, 2A, and 2B, the first source/drain patterns 300A may be provided on the active pattern AP on opposite sides of the first gate pattern G1. The active pattern AP between the first source/drain patterns 300A may serve as the channel region CHR of the first transistor 10. The first source/drain patterns 300A may have top surfaces higher than a topmost surface of the channel region CHR. The first source/drain patterns 300A may be epitaxial patterns. The epitaxial pattern may mean a pattern formed by an epitaxial growth process. The first source/drain patterns 300A may include a semiconductor material, such as silicon, germanium, silicon-germanium (SiGe), or silicon carbide (SiC).

First spacer patterns 210A may be provided on opposite sidewalls of the first gate pattern G1. The width of the first opening 290A may be substantially the same as an interval between adjacent first spacer patterns 210A. The first spacer patterns 210A may include a silicon oxide layer, a silicon nitride layer, or a silicon carbon nitride layer.

The second transistor 20 may be provided on the second region R2 of the substrate 100. The second transistor 20 may include second source/drain patterns 300B, a second gate dielectric pattern 400B, and a second gate pattern G2. The following describes the second transistor 20.

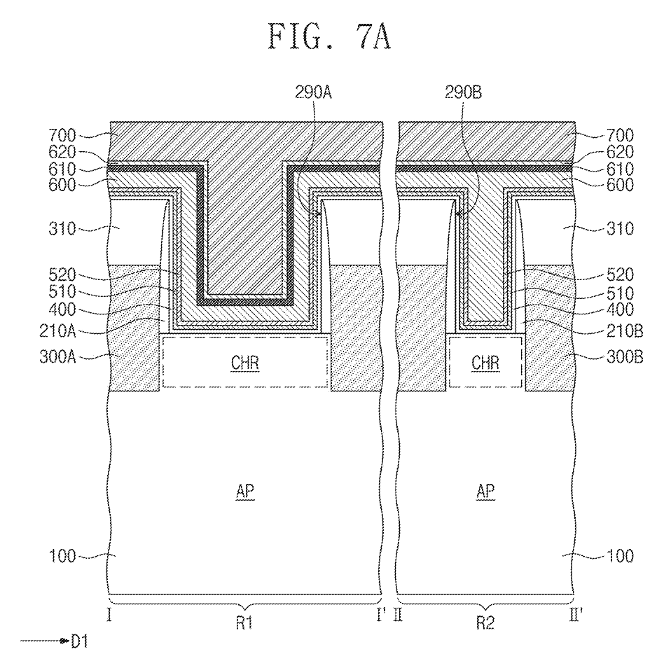

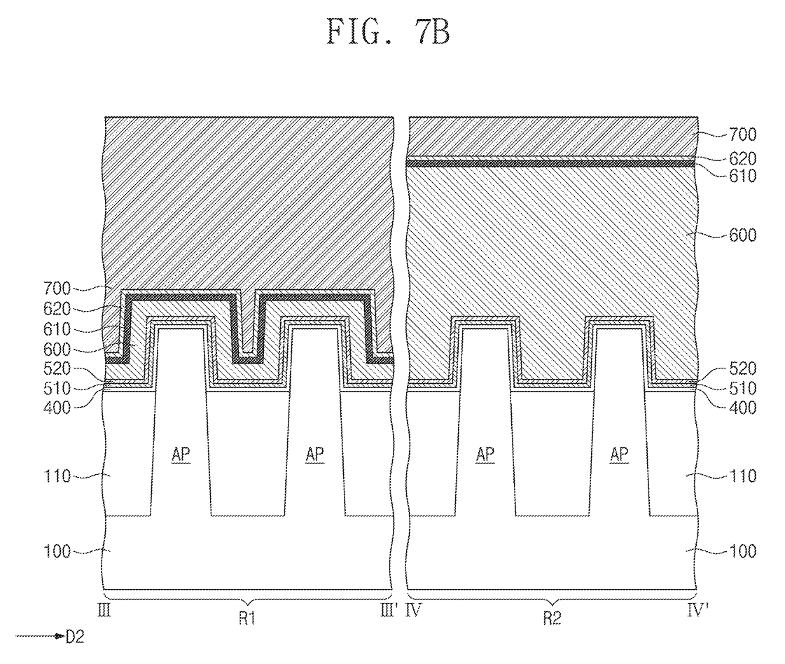

The second gate dielectric pattern 400B may extend on or cover a floor surface and a sidewall of the second opening 290B. The second gate dielectric pattern 400B may be disposed between the second gate pattern G2 and a channel region CHR of the active pattern AP of the second region R2 and between the second gate pattern G2 and the interlayer dielectric layer 310. The second gate dielectric pattern 400B may include a material the same as that of the first gate dielectric pattern 400A. For example, as shown in FIGS. 7A and 7B, the second gate dielectric pattern 400B and the first gate dielectric pattern 400A may be portions of a same layer 400.

The second gate pattern G2 may be provided in the second opening 290B of the interlayer dielectric layer 310. The second gate pattern G2 may extend in parallel to the second direction D2 and may extend across the active pattern AP. The active pattern AP below the second gate pattern G2 may be defined as the channel region CHR. The second gate pattern G2 may have a width W2 less than the width W1 of the first gate pattern G1. For example, the width W2 of the second gate pattern G2 may fall within a range from 1 nm to 20 nm.

The second gate pattern G2 may include second work function patterns 510B and 520B and a second conductive blocking pattern 600B. The second work function patterns 510B and 520B may include a second lower work function pattern 510B and a second upper work function pattern 520B which are stacked. The second work function patterns 510B and 520B may be provided on the floor surface and the sidewall of the second opening 290B. Each of the second lower work function pattern 510B and the second upper work function pattern 520B may be formed of a conductive material having a predetermined work function, and may contribute to controlling a threshold voltage of the channel region CHR of the active pattern AP. The second lower work function pattern 510B may include a material the same as that of the first lower work function pattern 510A (and in some embodiments may be portions of a same layer, e.g., layer 510 shown in FIGS. 7A-7B). The second upper work function pattern 520B may include a material the same as that of the first upper work function pattern 520A (and in some embodiments may be portions of a same layer, e.g., layer 520 shown in FIGS. 7A-7B). The second upper work function pattern 520B may have a work function different from that of the second lower work function pattern 510B. Differently from that shown, one or more of the second lower work function pattern 510B or the second upper work function pattern 520B may not be provided.

The second conductive blocking pattern 600B may be provided on the second upper work function pattern 520B and may fill the second opening 290B. The second conductive blocking pattern 600B may be in direct contact with the second upper work function pattern 520B. The second conductive blocking pattern 600B may include a material the same as that of the first conductive blocking pattern 600A (and in some embodiments may be portions of a same layer, e.g., layer 600 shown in FIGS. 7A-7B). The second conductive blocking pattern 600B may have a crystalline structure. The crystalline structure of the second conductive blocking pattern 600B may be the same as the crystalline structure of the first conductive blocking pattern 600A. The second conductive blocking pattern 600B may include a material different from those of the first blocking pattern 610A and the conductive pattern 700A. The first blocking pattern 610A, the second blocking pattern 620A, and the conductive pattern 700A may not extend into the second opening 290B.

The second source/drain patterns 300B may be provided on the active pattern AP on opposite sides of the second gate pattern G2. The channel region CHR of the active pattern AP may be provided between the second source/drain patterns 300B. The second source/drain patterns 300B may have top surfaces higher than a topmost surface of the channel region CHR. The second source/drain patterns 300B may include epitaxial growth patterns. The second source/drain patterns 300B may include a semiconductor material, such as silicon, germanium, silicon-germanium (SiGe), or silicon carbide (SiC).

Second spacer patterns 210B may be provided on opposite sidewalls of the second gate pattern G2. The second spacer patterns 210B may include a material the same as that of the first spacer patterns 210A. The second spacer patterns 210B may include a silicon oxide layer, a silicon nitride layer, or a silicon carbon nitride layer.

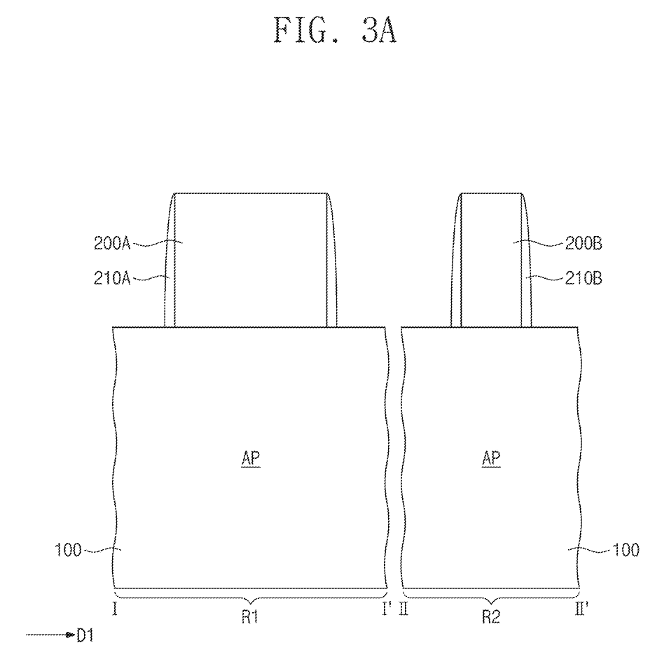

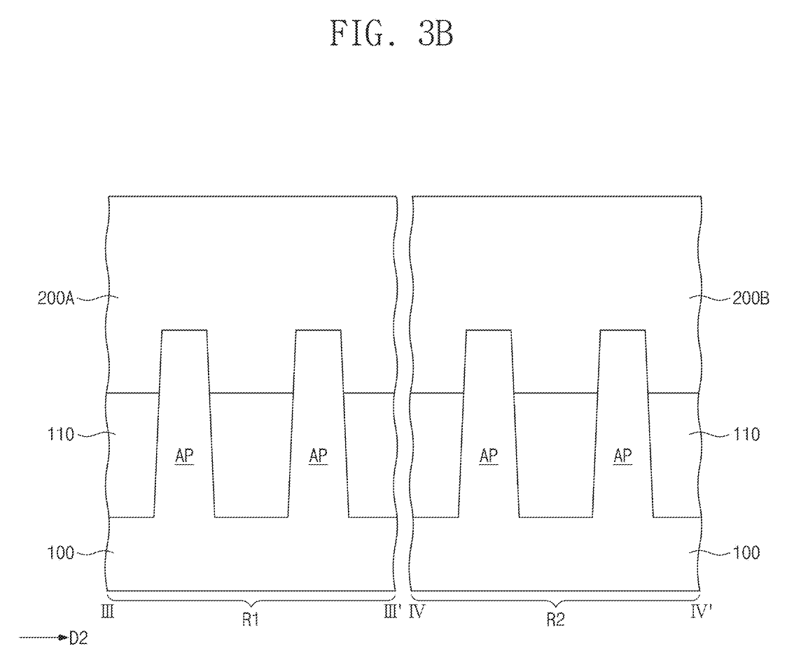

FIGS. 3A, 4A, 5A, 6A, and 7A illustrate cross-sectional views taken along lines I-I′ and II-IF of FIG. 1, showing methods of fabricating a semiconductor device according to example embodiments of inventive concepts. FIGS. 3B, 4B, 5B, 6B, and 7B illustrate cross-sectional views taken along lines and IV-IV′ of FIG. 1, showing methods of fabricating a semiconductor device according to example embodiments of inventive concepts. A description duplicate with the aforementioned will be omitted below.

Referring to FIGS. 1, 3A, and 3B, an active pattern AP may be formed to protrude from a substrate 100. The active pattern AP may extend in parallel to a first direction D1. For example, the formation of the active pattern AP may include forming a mask pattern (not shown) on the substrate 100, and then using the mask pattern as an etching mask to form a trench in the substrate 100. A dopant implantation process may be performed to implant a dopant into the active pattern AP. The dopant may be a p-type dopant (e.g., boron (B)) or an n-type dopant (e.g., phosphorous (P) or arsenic (As)).

A device isolation pattern 110 may be formed on the substrate 100, thereby extending on or covering opposite lower sidewalls of the active pattern AP. An upper portion of the active pattern AP may be exposed by the device isolation pattern 110. A shallow trench isolation (STI) method may be used to form the device isolation pattern 110.

A first sacrificial gate pattern 200A and a second sacrificial gate pattern 200B may be formed on the substrate 100. The first sacrificial gate pattern 200A may be formed on a first region R1 of the substrate 100, and the second sacrificial gate pattern 200B may be formed on a second region R2 of the substrate 100. The first and second sacrificial gate patterns 200A and 200B may extend in parallel to a second direction D2, while extending across the active pattern AP. Each of the first and second sacrificial gate patterns 200A and 200B may partially cover a portion of corresponding active pattern AP, and may expose other portion(s) of the corresponding active pattern AP. The first and second sacrificial gate patterns 200A and 200B may include polysilicon. The first and second sacrificial gate patterns 200A and 200B may be formed in a single or same process. The second sacrificial gate pattern 200B may have a width less than that of the first sacrificial gate pattern 200A.

First spacer patterns 210A and second spacer patterns 210B may be respectively formed on the first region R1 and the second region R2 of the substrate 100. The first spacer patterns 210A may be formed on opposite sidewalls of the first sacrificial gate pattern 200A. The second spacer patterns 210B may be formed on opposite sidewalls of the second sacrificial gate pattern 200B. In some embodiments, a spacer layer (not shown) may be conformally formed on the substrate 100, and thus the first and second sacrificial gate patterns 200A and 200B may be covered with the spacer layer. An etching process may be performed such that the spacer layer may be partially etched to form the first and second spacer patterns 210A and 210B.

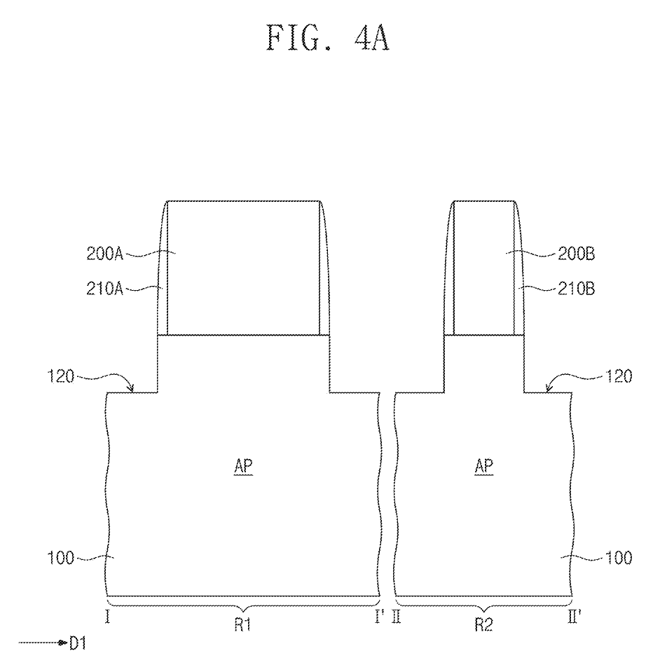

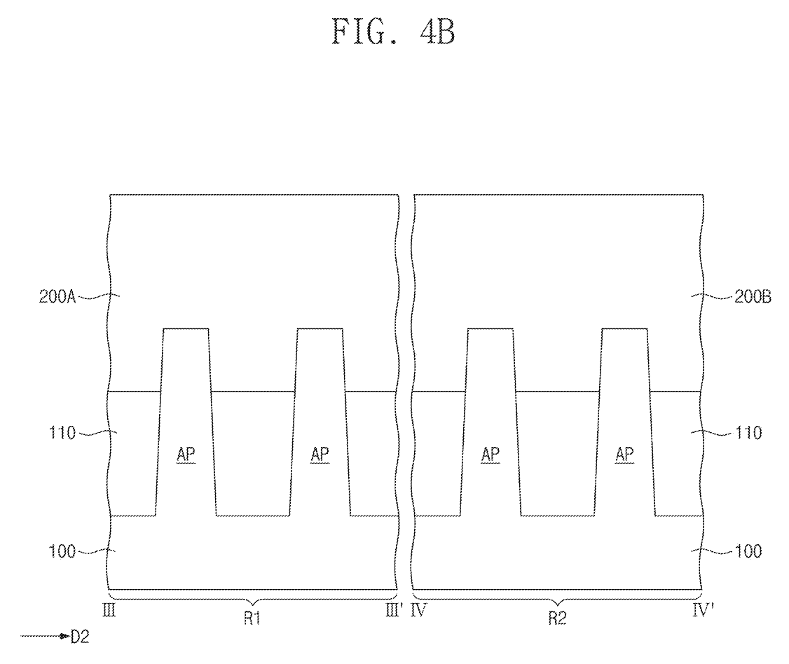

Referring to FIGS. 1, 4A, and 4B, recessions 120 may be formed in the active pattern AP by etching the active pattern AP exposed by the first and second sacrificial gate patterns 200A and 200B and the first and second spacer patterns 210A and 210B. The recessions 120 may have floor surfaces lower than a topmost surface of the active pattern AP. The recessions 120 may be formed on opposite sides of each of the first and second sacrificial gate patterns 200A and 200B.

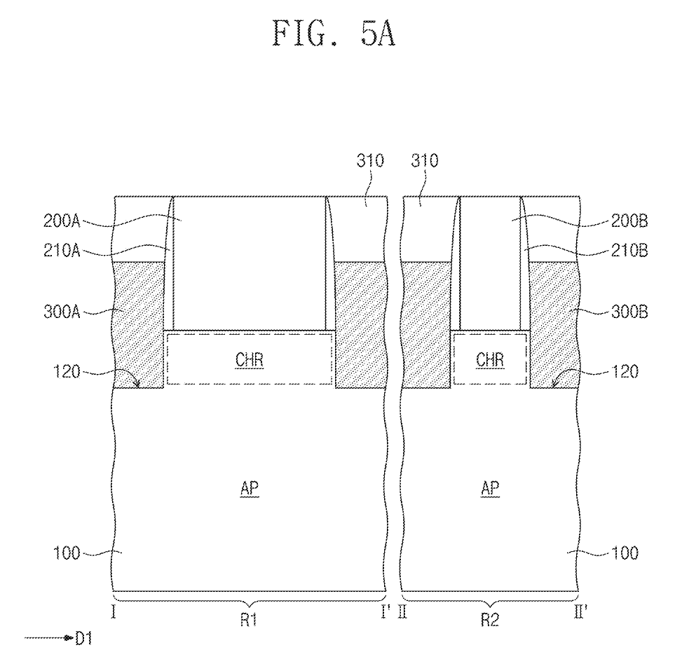

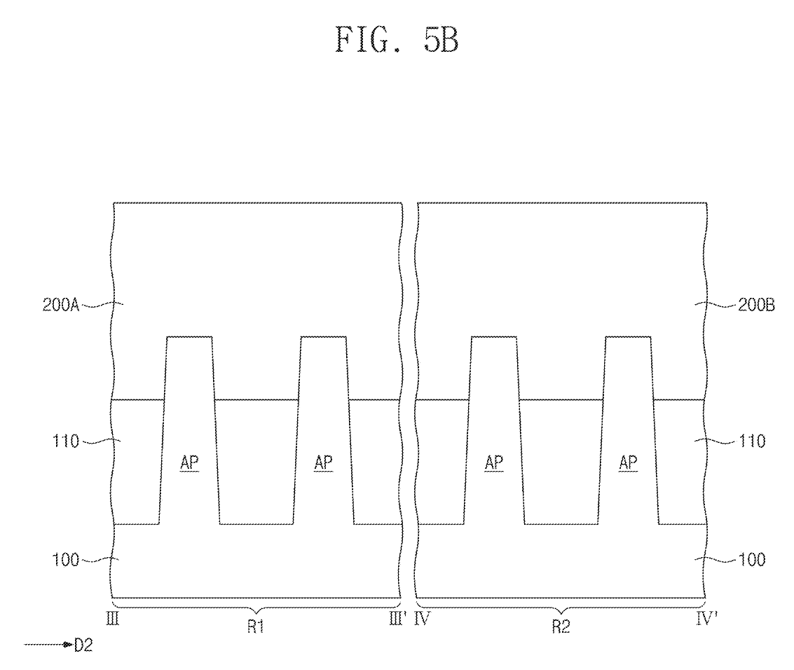

Referring to FIGS. 1, 5A and 5B, first source/drain patterns 300A and second source/drain patterns 300B may be respectively formed on the first region R1 and the second region R2 of the substrate 100. The first source/drain patterns 300A may be formed on the active pattern AP on opposite sides of the first sacrificial gate pattern 200A. The second source/drain patterns 300B may be formed on the active pattern AP on opposite sides of the second sacrificial gate pattern 200B. The first and second source/drain patterns 300A and 300B may be formed by growing epitaxial patterns from the recessions 120 of the active pattern AP. The formation of the first and second source/drain patterns 300A and 300B may define channel regions CHR, one of which is formed in the active pattern AP between the first source/drain patterns 300A and the other of which is formed in the active pattern AP between the second source/drain patterns 300B.

An interlayer dielectric layer 310 may be formed to extend on or cover the first and second source/drain patterns 300A and 300B. The interlayer dielectric layer 310 may include one or more of a silicon oxide layer, a silicon nitride layer, a silicon oxynitride layer, or a low-k dielectric layer.

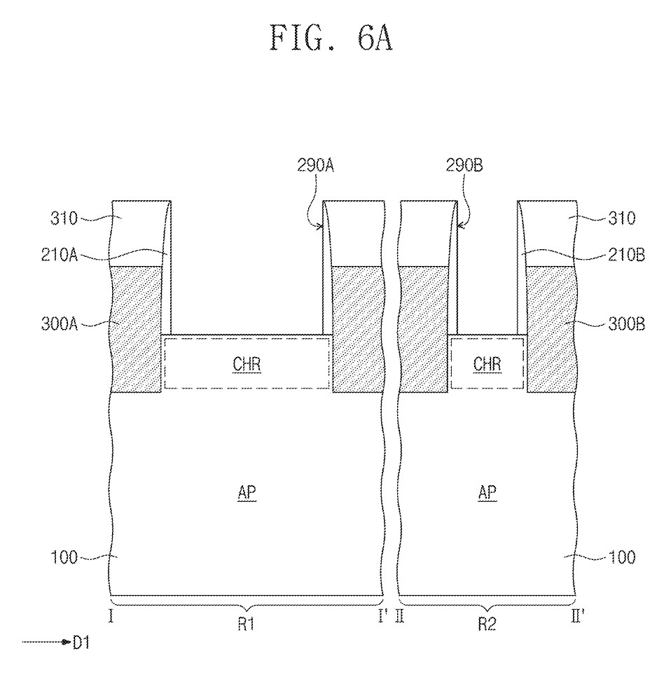

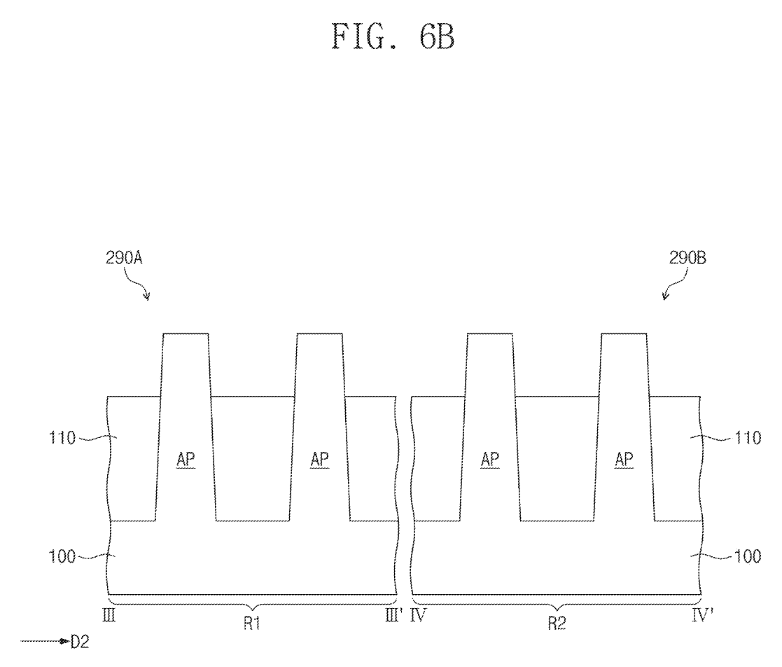

Referring to FIGS. 1, 6A, and 6B, a first opening 290A and a second opening 290B may be formed in the interlayer dielectric layer 310. In some embodiments, the first sacrificial gate pattern 200A may be removed to form the first opening 290A. The first opening 290A may be provided between the first spacer patterns 210A and may expose the channel region CHR of the active pattern AP on the first region R1 of the substrate 100. The first opening 290A may have a width substantially the same as the width of the first sacrificial gate pattern 200A. Likewise, the second sacrificial gate pattern 200B may be removed to form the second opening 290B. The second opening 290B may be provided between the second spacer patterns 210B and may expose the channel region CHR of the active pattern AP on the second region R2 of the substrate 100. The second opening 290B may have a width substantially the same as the width of the second sacrificial gate pattern 200B. The width of the first opening 290A may be greater than the width of the second opening 290B.

Referring to FIGS. 1, 7A, and 7B, a gate dielectric layer 400, a lower work function layer 510, an upper work function layer 520, a conductive blocking layer 600, a first blocking layer 610, a second blocking layer 620, and a conductive layer 700 may be formed on the first and second regions R1 and R2 of the substrate 100. For example, the gate dielectric layer 400 may be conformally formed on a floor surface and a sidewall of the first opening 290A, a floor surface and a sidewall of the second opening 290B, and a top surface of the interlayer dielectric layer 310. As shown in FIG. 7B, the gate dielectric layer 400 may extend on or cover a sidewall and a topmost surface of the channel region CHR of the active pattern AP. The gate dielectric layer 400 may include, for example, silicon oxide, silicon nitride, silicon oxynitride, or a high-k dielectric material.

The lower work function layer 510 may be conformally formed on the gate dielectric layer 400. The lower work function layer 510 may extend into the first and second openings 290A and 290B.

The upper work function layer 520 may be conformally formed on the lower work function layer 510. The upper work function layer 520 may extend into the first and second openings 290A and 290B.

The conductive blocking layer 600 may be formed on the upper work function layer 520. A deposition process may be used to form the conductive blocking layer 600. As discussed above, the width of the first opening 290A may be greater than the width of the second opening 290B. The formation of the conductive blocking layer 600 may continue until the second opening 290B is completely filed and the first opening 290A is not completely filled. The conductive blocking layer 600 may be formed on the sidewall and the floor surface of the first opening 290A, thereby extending on or covering the upper work function layer 520. The conductive blocking layer 600 may be formed on the top surface of the interlayer dielectric layer 310. The conductive blocking layer 600 may have a crystalline structure. The conductive blocking layer 600 may include metal nitride.

The first blocking layer 610 may be formed to extend on or cover the conductive blocking layer 600. The first blocking layer 610 may extend into the first opening 290A. For example, the first blocking layer 610 may conformally extend on or cover the conductive blocking layer 600 in the first opening 290A. The first blocking layer 610 may not extend into the second opening 290B. The first blocking layer 610 may have an amorphous structure. As such, the second opening 290B may be free of layers or patterns having the amorphous structure of the first blocking layer 610. The first blocking layer 610 may have a thickness less than that of the conductive blocking layer 600. For example, the first blocking layer 610 may have a thickness ranging from more than 0 Å to equal to or less than 50 Å. Each of the thicknesses of the conductive blocking layer 600 and the first blocking layer 610 may be a value measured on the first region R1 of the substrate 100. A deposition process may be used to form the first blocking layer 610.

The second blocking layer 620 may be formed on the first blocking layer 610. The second blocking layer 620 may conformally extend on or cover the first blocking layer 610 in the first opening 290A. For example, the second blocking layer 620 may be provided on the floor surface and the sidewall of the first opening 290A. The second blocking layer 620 may extend onto the top surface of the interlayer dielectric layer 310. The second blocking layer 620 may not be provided in the second opening 290B. The second blocking layer 620 may have a crystalline structure. The second blocking layer 620 may be formed of a material having an excellent adhesion to the first blocking layer 610. For example, the second blocking layer 620 may include a material the same as that of the conductive blocking layer 600. A deposition process may be used to form the second blocking layer 620.

The conductive layer 700 may be formed on the first and second regions R1 and R2 of the substrate 100, thereby extending on or covering the second blocking layer 620. The conductive layer 700 may fill the first opening 290A and extend onto the top surface of the interlayer dielectric layer 310. The conductive layer 700 may be in direct contact with the second blocking layer 620. The material of the second blocking layer 620 may be properly controlled or selected to make the second blocking layer 620 have an excellent adhesion to the conductive layer 700. The conductive layer 700 may thus be satisfactorily adhered to the second blocking layer 620. The conductive layer 700 may include a material such as that described in the example of the conductive pattern 700A shown in FIGS. 1, 2A, and 2B.

As discussed with reference to FIG. 2C, when the second blocking layer 620 and the conductive layer 700 are formed, the first blocking layer 610 may prevent impurities from being introduced into the gate dielectric layer 400.

Referring back to FIGS. 1, 2A, and 2B, the gate dielectric layer 400, the lower work function layer 510, the upper work function layer 520, the conductive blocking layer 600, the first blocking layer 610, the second blocking layer 620, and the conductive layer 700 may be planarized to form a first gate dielectric pattern 400A, a first gate pattern G1, a second gate dielectric pattern 400B, and a second gate pattern G2. The first gate dielectric pattern 400A and the first gate pattern G1 may be formed in the first opening 290A. The second gate dielectric pattern 400B and the second gate pattern G2 may be formed in the second opening 290B.

The planarization may be achieved by performing an etch-back process or a chemical mechanical polishing process. The planarization may continue until removal of the gate dielectric layer 400, the lower work function layer 510, the upper work function layer 520, the conductive blocking layer 600, the first blocking layer 610, the second blocking layer 620, and the conductive layer 700 from the top surface of the interlayer dielectric layer 310. After the planarization process, the interlayer dielectric layer 310 may be exposed. Therefore, the first gate pattern G1 and the second gate pattern G2 may be separated from each other.

In some embodiments, the gate dielectric layer 400 may be planarized to form the first and second gate dielectric patterns 400A and 400B. The lower work function layer 510 may be planarized to form first and second lower work function patterns 510A and 510B. The upper work function layer 520 may be planarized to form first and second upper work function patterns 520A and 520B. The conductive blocking layer 600 may be planarized to form first and second conductive blocking patterns 600A and 600B. The first blocking layer 610, the second blocking layer 620, and the conductive layer 700 may be planarized to respectively form a first blocking pattern 610A, a second blocking pattern 620A, and a conductive pattern 700A. The first and second lower work function patterns 510A and 510B, the first and second upper work function patterns 520A and 520B, the first and second conductive blocking patterns 600A and 600B, the first and second blocking patterns 610A and 620A, and the conductive pattern 700A may be the same as those discussed above. For example, the conductive pattern 700A may fill the first opening 290A. The first blocking pattern 610A, the second blocking pattern 620A, and the conductive pattern 700A may not extend into the second opening 290B. The second conductive blocking pattern 600B may fill the second opening 290B. As such, the second opening 290B may be free of the material of the conductive pattern 700A. In other words, the material 600B filling the second gate pattern G2 may be different from the material 700A filling the first gate pattern G1.

As discussed above with reference to FIG. 2C, when the first gate pattern G1 is formed, the first blocking pattern 610A may prevent impurities from being introduced into the gate dielectric layer 400. In addition, the conductive blocking layer 600, the first blocking layer 610, and the second blocking layer 620 may prevent impurities from being introduced into the first gate dielectric pattern 400A in a subsequent process. The subsequent process may include a process for forming a gate contact (not shown) on the first gate pattern G1.

According to inventive concepts, a gate pattern may include a plurality of stacked blocking patterns and a conductive pattern. The blocking patterns may prevent impurities from being introduced into a gate dielectric pattern. As a result, a semiconductor device may have improved threshold voltage characteristics.

Although the present invention has been described in connection with the embodiments of inventive concepts illustrated in the accompanying drawings, it will be understood by one of ordinary skill in the art that variations in form and detail may be made therein without departing from the spirit and essential feature of inventive concepts. It will be apparent to those skilled in the art that various substitution, modifications, and changes may be thereto without departing from the scope and spirit of the inventive concepts.

What is claimed is:

1. A semiconductor device, comprising:
a substrate;
an interlayer dielectric layer on the substrate and comprising a first opening and a second opening therein;
a first gate pattern in the first opening and comprising a first work function pattern, a first conductive blocking pattern, a first blocking pattern, and a conductive pattern that are stacked in the first opening; and
a second gate pattern in the second opening,
wherein the second gate pattern comprises:
a second work function pattern, wherein the second work function pattern and the first work function pattern comprise a same material; and
a second conductive blocking pattern on the second work function pattern in the second opening,
wherein the second conductive blocking pattern comprises a material that is different from a material of the conductive pattern and is different from a material of the first blocking pattern.

2. The semiconductor device of claim 1, wherein a width of the first gate pattern is greater than a width of the second gate pattern.

3. The semiconductor device of claim 1, wherein the second conductive blocking pattern and the first conductive blocking pattern comprise a same material.

4. The semiconductor device of claim 1, wherein the first gate pattern further comprises a second blocking pattern between the first blocking pattern and the conductive pattern.

5. The semiconductor device of claim 4, wherein the second blocking pattern and the first conductive blocking pattern comprise a same material.

6. The semiconductor device of claim 1, wherein:
the first blocking pattern comprises an amorphous structure;
the first conductive blocking pattern comprises a crystalline structure; and
the second opening is free of patterns having the amorphous structure of the first blocking pattern therein.

7. The semiconductor device of claim 1, wherein the second conductive blocking pattern is in direct contact with the second work function pattern, and wherein the second opening is free of the material of the conductive pattern therein.

8. A semiconductor device, comprising:
a substrate comprising an active pattern; and
a first gate pattern extending across the active pattern,
wherein the first gate pattern comprises:
a first work function pattern on the substrate;
a first conductive blocking pattern on the first work function pattern;
a first blocking pattern on the first conductive blocking pattern and comprising an amorphous structure; and
a conductive pattern on the first blocking pattern.

9. The semiconductor device of claim 8, wherein the first conductive blocking pattern comprises a crystalline structure.

10. The semiconductor device of claim 8, wherein the first gate pattern further comprises a second blocking pattern between the first blocking pattern and the conductive pattern.

11. The semiconductor device of claim 10, wherein the second blocking pattern and the first conductive blocking pattern comprise a same material and comprise a crystalline structure.

12. The semiconductor device of claim 8, further comprising an interlayer dielectric layer on the substrate and comprising a first opening therein,
wherein the first gate pattern is provided in the first opening, and
wherein the conductive pattern fills the first opening.

13. The semiconductor device of claim 12, further comprising a second gate pattern in a second opening of the interlayer dielectric layer,
wherein the second gate pattern comprises:
a second work function pattern, wherein the second work function pattern and the first work function pattern comprise a same material; and
a second conductive blocking pattern on the second work function pattern and filling the second opening,
wherein the second conductive blocking pattern and the first conductive blocking pattern comprise a same material, and
wherein the second opening is free of patterns having the amorphous structure of the first blocking pattern therein.

14. A semiconductor device, comprising:
a substrate;
an interlayer dielectric layer on the substrate and having a first opening and a second opening therein;
a first gate pattern in the first opening; and
a second gate pattern in the second opening,
wherein the first gate pattern comprises:
a first upper work function pattern on a floor surface and a sidewall of the first opening;
a first conductive blocking pattern on the first upper work function pattern;
a first blocking pattern on the first conductive blocking pattern; and
a conductive pattern on the first blocking pattern and in the first opening, and wherein the second gate pattern comprises:
a second upper work function pattern, wherein second upper work function pattern and the first upper work function pattern comprise a same material; and
a second conductive blocking pattern on the second upper work function pattern and in the second opening,
wherein the second conductive blocking pattern and the first conductive blocking pattern comprise a same material.

15. The semiconductor device of claim 14, wherein a width of the first opening is greater than a width of the second opening.

16. The semiconductor device of claim 14, wherein the first gate pattern further comprises a second blocking pattern between the first blocking pattern and the conductive pattern.

17. The semiconductor device of claim 14, wherein the second conductive blocking pattern and the first blocking pattern comprise different materials.

18. The semiconductor device of claim 14, wherein the first blocking pattern comprises an amorphous structure, and wherein the second opening is free of patterns having the amorphous structure of the first blocking pattern.

19. The semiconductor device of claim 14, further comprising:
a first gate dielectric pattern between the first opening and the first gate pattern; and
a second gate dielectric pattern between the second opening and the second gate pattern,
wherein the second gate dielectric pattern and the first gate dielectric pattern comprise a same material.

20. The semiconductor device of claim 14, wherein
the first gate pattern further comprises a first lower work function pattern between the first opening and the first upper work function pattern, and
the second gate pattern further comprises a second lower work function pattern between the second opening and the second upper work function pattern,
wherein the second lower work function pattern and the first lower work function pattern comprise a same material.
